(19) United States
(12) Patent Application Publication
(10) Pub. No.: US 2026/0082502 A1
(43) Pub. Date: Mar. 19, 2026

(54) CABINET

(71) Applicant: Fullian Precision Electronics (Tianjin) Co., LTD., Tianjin (CN)

(72) Inventors: Kun-Yang Cheng, New Taipei (TW); Kai-Sheng Chang, New Taipei (TW); Chen-Hao Su, New Taipei (TW); Fang-Xing Yang, Tianjin (CN); Liang Gao, Tianjin (CN); Wen-Tzu Chen, New Taipei (TW)

(21) Appl. No.: 18/960,037

(22) Filed: Nov. 26, 2024

(30) Foreign Application Priority Data
Sep. 14, 2024 (CN) 202411295784.5

(51) Int. Cl. H05K 7/14

(52) U.S. Cl. CPC H05K 7/1489

(57) ABSTRACT

A cabinet is disclosed in the present application. The cabinet includes a cabinet body, a chassis, a drawer module, and a locking mechanism. The chassis is provided in the cabinet body and can be withdrawn from the cabinet body. The drawer module is provided in the chassis and withdrawable from the chassis. The locking mechanism includes a rotating member and a locking member. The rotating member is rotatably disposed in the drawer module and is in contact with the chassis. The locking member is movably disposed in the chassis to be located at or away from a rotation path of the rotating member. The drawer module is restricted from being withdrawn from the chassis when the rotating member is abutted against the chassis. The drawer module is allowed to be withdrawn from the chassis when the rotating member is separated from the chassis.

### FIELD

The present application relates to the field of servers, particularly to a cabinet.

### BACKGROUND

The server cabinet usually includes a cabinet body, a chassis, and a drawer module, the chassis is disposed in the cabinet body and can be withdrawn from the cabinet in a certain direction, while the drawer module is disposed in the chassis and is withdrawn from the chassis in that direction. When the chassis is withdrawn from the cabinet body and the drawer module is pulled out from the chassis, the chassis and the drawer module are in a suspended state at the same time, and the center of gravity of the chassis and the drawer module as a whole is far away from the cabinet body, which a larger moment of force may be exerted on the cabinet body, easily leading to deformation or even fracture damage to the cabinet body.

Therefore, improvement is desired.

### BRIEF DESCRIPTION OF THE DRAWINGS

Implementations of the present application will now be described, by way of embodiments, with reference to the attached figures.

FIG. 1 is a schematic diagram of an embodiment of a drawer module and a chassis withdrawn from a cabinet of the present application.

FIG. 2 is a partial schematic diagram of an embodiment of a locking mechanism applied to the drawer module and the chassis of the present application.

FIG. 3 is a schematic diagram of an embodiment of to the drawer module and the chassis in a locked state of the present application.

FIG. 4 is a schematic diagram of an embodiment of to the drawer module and the chassis in an unlocked state the present application.

FIG. 5 is a schematic diagram of an embodiment of a locking member located at a rotation path of a rotating member.

FIG. 6 is an exploded view of an embodiment of the locking mechanism in a first perspective.

FIG. 7 is an exploded view of an embodiment of the locking mechanism in a second perspective.

FIG. 8 is a partial schematic diagram of an embodiment of the locking member located at a first section.

FIG. 9 is a partial schematic diagram of an embodiment of the locking member located at a second section.

FIG. 10 is a partial schematic diagram of an embodiment of the locking member located at a third section.

### DETAILED DESCRIPTION

The technical solutions in the embodiments of the present application will be described below in conjunction with the accompanying drawings in the embodiments of the present application, and the described embodiments are only a portion of the embodiments of the present application and not all of the embodiments.

When a component is considered to be “connected” to another component, it may be directly connected to another component or there may be a centered component between the component and another component.

Unless otherwise specified, the term “plurality”as used herein refers to two or more.

In the embodiment of the present application, the words “first” and “second” are only used to distinguish different objects and cannot be understood as indicating or implying relative importance, or as indicating or implying order. For example, the first application and the second application are used to distinguish different applications, not to describe the specific order of applications.

The term “orthogonal” is used to describe an ideal state between two components. In the actual state of production or use, an approximately orthogonal state may exist between the two components.

The term “parallel” is used to describe an ideal state between two components. In the actual state of production or use, an approximate parallelism between the two components may exist between the two components.

Unless otherwise defined, all technical and scientific terms used herein have the same meaning as commonly understood by those skilled in the art belonging to the present application. The terms used herein in the specification of the present application are used only for the purpose of describing specific embodiments and are not intended to limit the present application.

The present application provides a cabinet, the cabinet includes a cabinet body, a chassis, a drawer module, and a locking mechanism. The chassis is disposed in the cabinet body, and the chassis is withdrawable from the cabinet body along a first direction. The drawer module is disposed in the chassis, and the drawer module is withdrawable from the chassis along the first direction. The locking mechanism includes a rotating member and a locking member, the rotating member is rotationally disposed in the drawer module and the rotating member abuts against the chassis, a rotation plane of the rotating member is parallel to the first direction; the locking member is movably disposed in the chassis along a second direction to be located at or away from a rotation path of the rotating member, and the second direction is orthogonal to the rotation plane of the rotating member. A state of the rotating member against the chassis is a locked state, and the drawer module is restricted from being withdrawn from the chassis under the locked state; the rotating member is separated from the chassis during rotation, a state in which the rotating member is separated from the chassis is an unlocked state, and the drawer module is allowed to be withdrawn from the chassis under the unlocked state; and when the chassis is withdrawn from the cabinet body, the rotating member abuts against the chassis, the locking member is located at the rotation path of the rotating member, and the chassis cooperates with the locking member to limit rotation of the rotating member.

Before the chassis is withdrawn from the cabinet body, the drawer module can be withdrawn from the chassis normally by rotating the rotating member and separating it from the chassis. After the chassis is withdrawn from the cabinet body, the rotating member abuts against the chassis and the locking member is located at the rotation path of the rotating member, the chassis and the locking member cooperate to limit the rotation of the rotating member, and at this time, the rotating member is limited to rotate and not be able to be transformed from a locked state to an unlocked state, and the drawer module is limited to be withdrawn from the chassis, it is beneficial to keep the overall center of gravity of the chassis and the drawer module closer to the cabinet body, thereby reducing the possibility of deformation or even breakage of the cabinet during use.

Embodiments of the present application will be described below in connection with the accompanying drawings. The following embodiments and features in the embodiments may be combined with each other without conflict.

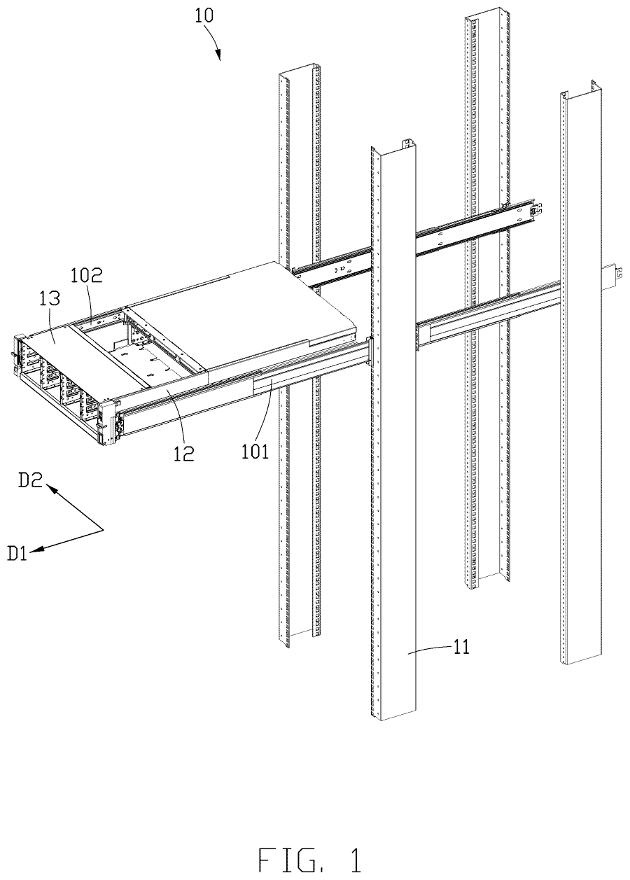

FIG. 1 illustrates a cabinet 10 in accordance with an embodiment of the present application.

The cabinet 10 includes a cabinet body 11, a chassis 12, and a drawer module 13. The chassis 12 is withdrawable from the cabinet 11 along a first direction D1, the drawer module 13 is disposed in the chassis 12, and the drawer module 13 is withdrawable from the chassis 12 along the first direction D1.

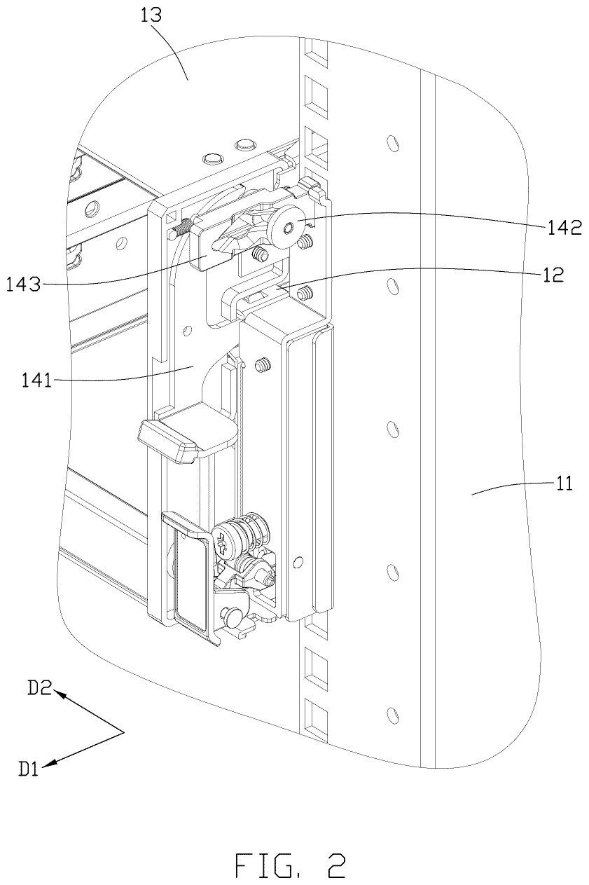

In some embodiments, referring to FIG. 2, the cabinet 10 further includes a locking mechanism 14, the locking mechanism 14 is used to lock the drawer module 13 and the chassis 12, thereby restricting the drawer module 13 from being withdrawn from the chassis 12 in an undesired situation. In some embodiments, the undesired situation refers to a situation where the chassis 12 has been withdrawn from the cabinet body 11.

In some embodiments, referring to FIG. 2, the locking mechanism 14 includes a rotating member 141, the rotating member 141 is rotationally disposed in the drawer module 13, the rotating member 141 abuts against the chassis 12, and a rotation plane of the rotating member 141 is parallel to the first direction D1.

The state in which the rotating member 141 abuts against the chassis 12 is a locked state, and in the locked state, the drawer module 13 is restricted from being withdrawn from the chassis 12. The rotating member 141 is separated from the chassis 12 during rotation, and the state in which the rotating member 141 is separated from the chassis 12 is an unlocked state, and in the unlocked state, the drawer module 13 is allowed to be withdrawn from the chassis 12.

In some embodiments, referring to FIG. 2, the locking mechanism 14 further includes a locking member 142, the locking member 142 is movably disposed in the chassis 12 along a second direction D2 to be located at or away from the rotation path of the rotating member 141, the second direction D2 is orthogonal to the rotation plane of the rotating member 141.

In some embodiments, after the chassis 12 is withdrawn from the cabinet body 11, the rotating member 141 abuts against the chassis 12, and the locking member 142 is located at the rotation path of the rotating member 141, and the chassis 12 cooperates with the locking member 142 to limit the rotation of the rotating member 141.

Before the chassis 12 is withdrawn from the cabinet body 11, the drawer module 13 can be withdrawn normally from the chassis 12 by causing the rotating member 141 to rotate and separate from the chassis 12. After the chassis 12 is withdrawn from the cabinet body 11, the rotating member 141 abuts against the chassis 12 and the locking member 142 is located at the rotation path of the rotating member 141, and the chassis 12 cooperates with the locking member 142 to limit the rotation of the rotating member 141. At this time, the rotating member 141 is restricted to rotate and cannot be changed from a locked state to an unlocked state, and the drawer module 13 is restricted from being withdrawn from the chassis 12, so that the center of gravity of the chassis 12 and the drawer module 13 as a whole is closer to the cabinet body 11, which is conducive to reducing the possibility of deformation or even fracture damage to the cabinet 10 when in use.

In some embodiments, referring to FIG. 1, the cabinet body 11 is provided with a first slide rail 101, and the chassis 12 is slidably disposed on the first slide rail 101. The first slide rail 101 facilitates a smoother withdrawal of the chassis 12 from the cabinet body 11.

In some embodiments, after the chassis 12 is withdrawn from the cabinet body 11, by restricting the drawer module 13 from being withdrawn from the chassis 12, it is beneficial to make the center of gravity of the chassis 12 and the drawer module 13 closer to the cabinet body 11, thereby reducing the possibility of deformation of the first slide rail 101.

In some embodiments, the chassis 12 is provided with a second slide rail 102, the drawer module 13 is slidably disposed on the second slide rail 102. The second slide rail 102 facilitates a smoother withdrawal of the drawer module 13 from the chassis 12.

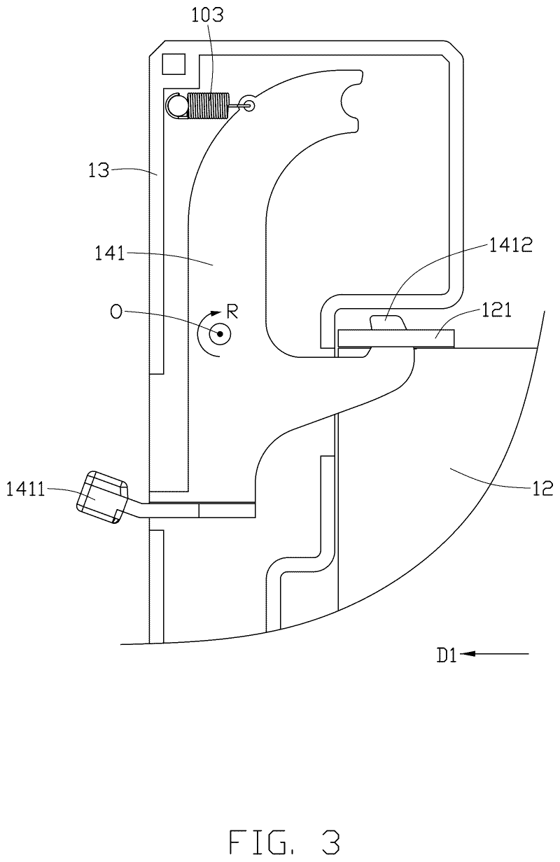

In some embodiments, by limiting the rotation of the rotating member 141 to limit the withdrawal of the drawer module 13 from the chassis 12. Referring to FIG. 3, the rotating member 141 rotates relative to the drawer module 13 along a rotation direction R1 at a rotation center O1.

In some embodiments, referring to FIG. 3, the rotating member 141 includes a grasping portion 1411, the grasping portion 1411 protrudes from the drawer module 13 along the first direction D1. the protruding grasping portion 1411 facilitates providing the operator with a position for gripping the rotating member 141, so as to facilitate the operator to rotate the rotating member 141 by means of the grasping portion 1411, or to withdraw the drawer module 13 from the chassis 12 along the first direction D1.

In some embodiments, referring to FIG. 3, an elastic member 103 is connected between the drawer module 13 and the rotating member 141, the elastic member 103 is used to keep the rotating member 141 abut against the chassis 12 before the rotating member 141 rotates. The present application may use the elastic member 103 to connect the drawer module 13 to the rotating member 141, which is beneficial for reducing the occurrence of unexpected rotation of the rotating member 141 under its own gravity, resulting in the cancellation of contact between the rotating member 141 and the drawer module 13, this is beneficial for reducing the situation where the drawer module 13 is allowed to be withdrawn from the chassis 12 without rotating the rotating member 141. Optionally, the elastic member 103 is a spring.

In some embodiments, before the rotating member 141 rotates, the elastic member 103 acts against the rotating member 141 along the opposite of the rotation direction R to keep the rotating member 141 abut against the chassis 12.

In some embodiments, the elastic member 103 is in a stretched state before the rotating member 141 rotates.

In some embodiments, referring to FIG. 3, the chassis 12 includes a first limiting portion 121, the rotating member 141 includes a second limiting portion 1412, and the first limiting portion 121 abuts against the second limiting portion 1412.

In some embodiments, before the rotating member 141 rotates, a projection of the second limiting portion 1412 partially overlaps with a projection of the first limiting portion 121 along the first direction D1, at this time, the drawer module 13 is restricted from being withdrawn from the chassis 12.

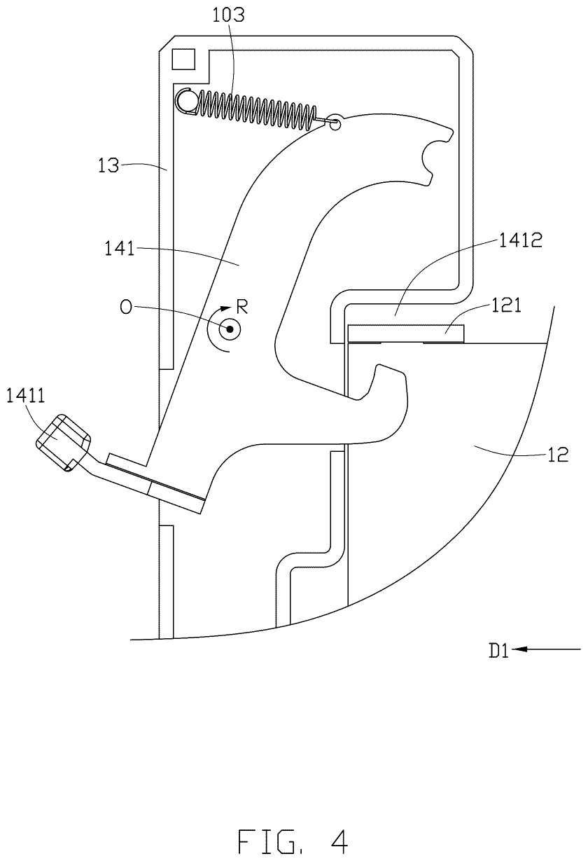

In some embodiments, referring to FIG. 4, after the rotating member 141 rotates along the rotation direction R, the second limiting portion 1412 is moved away from the first limiting portion 121, and the projection of the second limiting portion 1412 does not overlap with the projection of the first limiting portion 121 along the first direction D1, at this time, the drawer module 13 is allowed to be withdrawn from the chassis 12.

In some embodiments, referring to FIG. 4, after the rotating member 141 rotates along the rotation direction R, as the elastic member 103 connects the drawer module 13 and the rotating member 141, the elastic member 103 undergoes elastic deformation and has a tendency to recover. The elastic member 103 in this case can make the rotating member 141 to have a tendency to rotate along the opposite direction of the rotation direction R, this is beneficial for returning the rotating member 141 to the position where the projection of the second limiting portion 1412 partially overlaps with the projection of the first limiting portion 121 along the first direction D1.

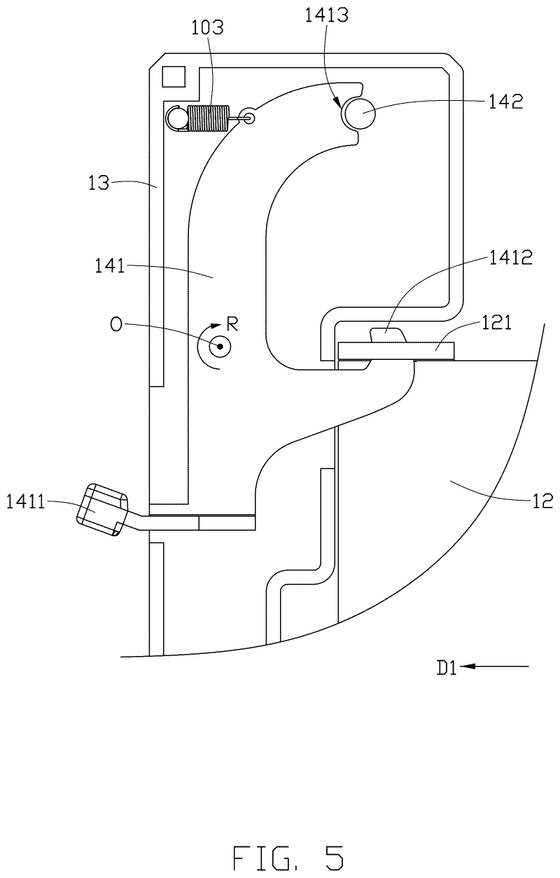

In some embodiments, referring to FIG. 5, the chassis 12 cooperates with the locking member 142 to limit the rotation of the rotating member 141, at this time, the rotation of the rotating member 141 along the first rotation direction R1 is stopped by the locking member 142, and the rotation of the rotating member 141 along the opposite direction of the rotation direction R is stopped by the first limiting portion 121. In this case, the first limiting portion 121 cooperates with the locking member 142 to limit the rotation of the rotating member 141, so that the drawer module 13 is restricted from being withdrawn from the chassis 12.

In some embodiments, referring to FIG. 5, the rotating member 141 includes a concave portion 1413 that contacts the locking member 142. When the concave portion 1413 is in contact with the locking member 142, the concave portion 1413 is disposed around a portion of the periphery of the locking member 142. When the concave portion 1413 is in contact with the locking member 142, the periphery of the locking member 142 will be partially disposed into the concave portion 1413, which is beneficial for the locking member 142 to more stably stop the rotating member 141.

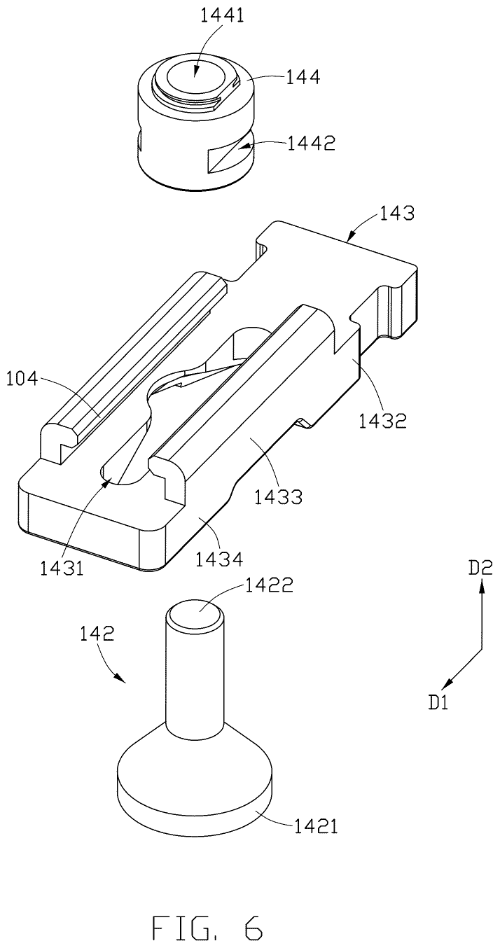

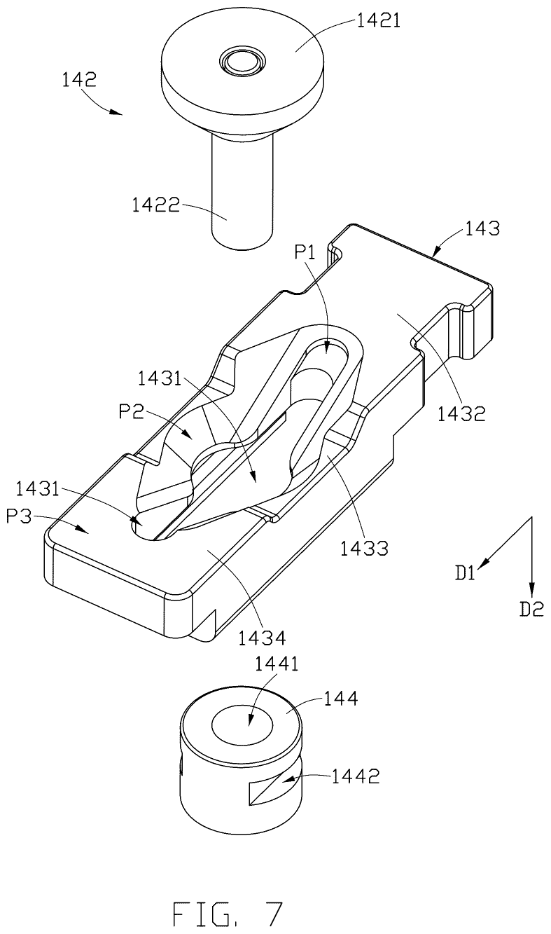

In some embodiments, referring to FIGS. 6 and 7, the locking mechanism 14 further includes a movable member 143, the movable member 143 defines a channel 1431 passing along the second direction D2, and the locking member 142 is movably disposed in the channel 1431.

In some embodiments, referring to FIGS. 6 and 7, the movable member 143 includes a first section 1432 and a second section 1433, the second section 1433 is connected to the first section 1432 along the first direction D1, and the channel 1431 is connected to the first section 1432 and the second section 1433. The first section 1432 is used to contact the locking member 142 and move the locking member 142 away from the rotation path of the rotating member 141, and the second section 1433 is used to contact the locking member 142 and position the locking member 142 in the rotation path of the rotating member 141.

In some embodiments, along the second direction D2, the second section 1433 is closer to the rotation plane of the rotating member 141 compared to the first section 1432. When the movable member 143 moves relative to the locking member 142 along the first direction D1, the locking member 142 moves from the first section 1432 to the second section 1433, and the locking member 142 can approach the rotation path of the rotating member 141 along the second direction D2; when the movable member 143 moves relative to the locking member 142 along the opposite direction of the first direction D1, the locking member 142 can move from the second section 1433 to the first section 1432 to move away from the rotation path of the rotating member 141 along the opposite direction of the second direction D2, which is beneficial for the locking member 142 to conveniently stop or cancel the stop of the rotating member 141.

In some embodiments, the second section 1433 transitionally connected to the first section 1432. In some embodiments, the second section 1433 is connected to the first section 1432 through sloping transition or curved transition.

In some embodiments, referring to FIG. 7, the first section 1432 includes a guiding surface P1, the guiding surface P1 is connected to the channel 1431, and the guiding surface P1 is used to guide the locking member 142 to move from the first section 1432 to the second section 1433. By the guiding effect of the guiding surface P1, the locking member 142 is moved from the first section 1432 to the second section 1433, which facilitates the locking member 142 to stop the rotating member 141 more easily.

In some embodiments, the angle between the guiding surface P1 and the second direction D2 is an acute angle.

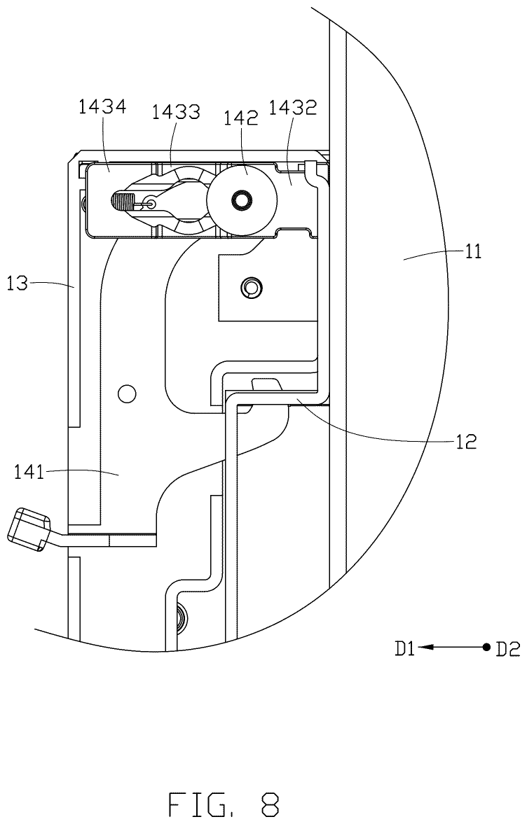

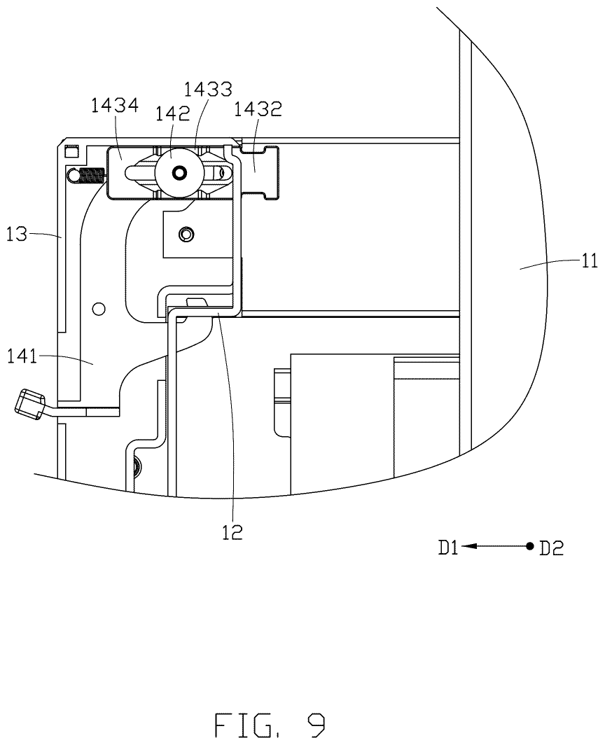

In some embodiments, the first section 1432 is further used to abut against the cabinet body 11 before the chassis 12 is withdrawn from the cabinet body 11, so as to keep the locking member 142 on the guiding surface P1; the first section 1432 is also used to detach from the cabinet body 11 after the chassis 12 is withdrawn from the cabinet body 11, so that the guiding surface P1 guides the locking member 142 to move from the first section 1432 to the second section 1433. Therefore, before the chassis 12 is withdrawn from the cabinet body 11, the locking member 142 is held in the first section 1432, and the locking member 142 is kept away from the rotation path of the rotating member 141, and the drawer module 13 can be withdrawn normally from the chassis 12 by causing the rotating member 141 to rotate (shown in FIG. 8); after the chassis 12 is withdrawn from the cabinet body 11, the locking member 142 moves to the second section 1433, the locking member 142 is located at the rotation path of the rotating member 141, the drawer module 13 cannot be withdrawn from the chassis 12 by causing the rotating member 141 to rotate (shown in FIG. 9). After withdrawing the chassis 12 from the cabinet body 11, the locking mechanism 14 can lock the drawer module 13 with the chassis 12, which can reduce the step of needing to further move the movable member 143, this will help improve the convenience of withdrawing the drawer module 13 from the chassis 12.

In some embodiments, referring to FIG. 7, the second section 1433 includes a positioning surface P2, the positioning surface P2 is connected to the channel 1431, and the positioning surface P2 is used to hold the locking member 142 on the second section 1433. When the locking member 142 is located on the positioning surface P2, the locking member 142 can be held on the second section 1433 and remain in the rotation path of the rotating member 141, which is conducive to improving the stability of stopping the rotating member 141.

In some embodiments, along the second direction D2, the positioning surface P2 is tapered. The tapered positioning surface P2 is conducive to forming a locking mechanism with the locking member 142 along the second direction D2, thereby making the locking member 142 more stably located on the positioning surface P2.

In some embodiments, referring to FIGS. 6 and 7, the movable member 143 also includes a third section 1434, the third section 1434 is connected to the second section 1433 along the first direction D1, and the channel 1431 is connected to the third section 1434.

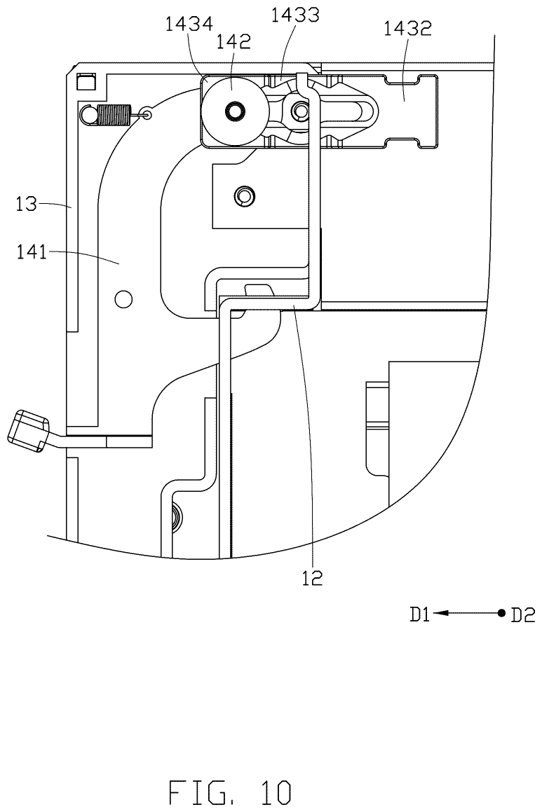

In some embodiments, along the second direction D2, the third section 1434 is further away from the rotation plane of the rotating member 141 compared to the second section 1433, and the third section 1434 is used to contact with the locking member 142 and maintain the locking member 142 away from the rotation path of the rotating member 141. When the chassis 12 is completely withdrawn from the cabinet body 11, since the guiding surface P1 guides the locking member 142 from the first section 1432 to the second segment second section 1433, such that the locking member 142 is located at the rotation path of the rotating member 141, thereby resulting in the drawer module 13 still being restricted from being withdrawn from the chassis 12. By moving the locking member 142 to the third section 1434 and keeping the locking member 142 away from the rotation path of the rotating member 141, it is beneficial to keep the locking member 142 to cancel the stopping of the rotating member 141, thereby facilitating the drawer module 13 to be allowed to be withdrawn from the chassis 12 after the chassis 12 is completely withdrawn from the cabinet body 11 (shown in FIG. 10).

In some embodiments, the third section 1434 transitionally connected to the second section 1433. In some embodiments, the third section 1434 is connected to the second section 1433 through sloping transition or curved transition.

In some embodiments, referring to FIG. 7, the third section 1434 includes a limiting surface P3, the limiting surface P3 is connected to the channel 1431, and the limiting surface P3 is used to hold the locking member 142 in the third section 1434. After the chassis 12 is completely withdrawn from the cabinet body 11, by positioning the locking member 142 on the limiting surface P3 and keeping the locking member 142 in the third section 1434, the locking member 142 can be stabilized away from the rotation path of the rotating member 141, thus facilitating the free withdrawal of the drawer module 13 from the chassis 12.

In some embodiments, the limiting surface P3 is orthogonal to the second direction D2.

In some embodiments, referring to FIGS. 6 and 7, the locking member 142 includes a cap portion 1421 and a rod portion 1422, the rod portion 1422 is connected to the cap portion 1421, the rod portion 1422 is movable in the channel 1431 and the cap portion 1421 contacts the movable member 143.

In some embodiments, along the second direction D2, the projection of part of the cap portion 1421 exceeds the projection of the channel 1431. When the rod portion 1422 moves in the channel 1431, the cap portion 1421 helps to restrict the locking member 142 from disengaging from the movable member 143 along the second direction D2, thereby improving the stability of the locking mechanism 14.

In some embodiments, the cap portion 1421 is a regular shape, such as a rounded or prismatic shape. In another embodiment, the cap portion 1421 is an irregularly shape.

In some embodiments, before the chassis 12 is withdrawn from the cabinet body 11, the first section 1432 is abutted against the cabinet body 11, such that the locking member 142 is located at the first section 1432, the end of the cap portion 1421 connected to the rod portion 1422 is located on the guiding surface P1 (in conjunction with FIGS. 7 and 8), and the rotating member 141 is allowed to rotate, and by rotating the rotating member 141, the drawer module 13 is allowed to be withdrawn from the chassis 12. In some embodiments, after the chassis 12 is withdrawn from the cabinet body 11, the first section 1432 is disengaged from the cabinet body 11, and the guiding surface P1 guides the locking member 142 to move from the first section 1432 to the second section 1433 until the locking member 142 is located at the second section 1433 and the side wall of the cap portion 1421 is attached to the positioning surface P2 (in conjunction with FIGS. 7 and 9). At this time, the rotating member 141 is restricted from rotating, and the drawer module 13 is restricted from being withdrawn from the chassis 12. In some embodiments, after the chassis 12 is completely withdrawn from the cabinet body 11, the movable member 143 is moved from the second section 1433 to the third section 1434 by reversing the movement of the locking member 142 relative to the locking member 142 along the first direction D1 until the locking member 142 is located at the third section 1434, and the end of the cap portion 1421 connected to the rod portion rod portion 1422 is attached to the limiting surface P3 (in conjunction with FIGS. 7 and 10). At this time, the rotating member 141 is allowed to rotate, and by rotating the rotating member 141, the drawer module 13 is allowed to be withdrawn from the chassis 12.

In some embodiments, along the second direction D2, the third section 1434 is further away from the rotation plane of the rotating member 141 compared to the second section 1433, and the third section 1434 is closer to the rotation plane of the rotating member 141 compared to the first section 1432.

In some embodiments, referring to FIGS. 6 and 7, the locking mechanism 14 further includes an auxiliary member 144, the auxiliary member 144 is slidably disposed on the movable member 143, the auxiliary member 144 defines a through hole 1441 that penetrates along the second direction D2.

In some embodiments, along the second direction D2, the projection of the through hole 1441 is located within the projection of the channel 1431, and the rod portion 1422 is movable in the through hole 1441 to be located at or away from the rotation path of the rotating member 141. When the movable member 143 moves relative to the locking member 142, the rod portion 1422 is movable in the through hole 1441, which facilitates reducing the likelihood that the rod portion 1422 will deviate from the second direction D2, and thus facilitates keeping the rod portion 1422 of the locking member 142 accurately located at or away from the rotation path of the rotating member 141.

In some embodiments, the movable member 143 is provided with a third slide rail 104, and the auxiliary member 144 includes a slide groove 1442, the slide groove 1442 slidingly cooperates with the third slide rail 104. Therefore, it is favorable for the movable member movable member 143 to move more smoothly relative to the auxiliary member auxiliary member 144, so that the movable member 143 can smoothly move relative to the auxiliary member 144, and the locking member 142 can smoothly move between the first section 1432, the second section 1433, and the third section 1434.

In another embodiment, the movable member 143 is provided with a slide groove 1442, and the auxiliary member 144 includes a third slide rail 104. The slide groove 1442 slidingly cooperates the third slide rail 104. The present application does not limit the manner in which the movable member 143 slides with the auxiliary member 144.

The process of using the cabinet 10 of the present application is as follows:

Before the drawer module 13 is withdrawn from the chassis 12 and the chassis 12 is withdrawn from the cabinet body 11, the first section 1432 of the movable member 143 abuts against the cabinet body 11, such that the locking member 142 is located at the first section 1432 to keep the away from the rotation path of the rotating member 141, and the rotating member 141 is allowed to rotate. By operating the grasping portion 1411 to rotate the rotating member 141, and the rotating member 141 is separated from the chassis 12. In the unlocked state, the drawer module 13 is withdrawn from the chassis 12.

Before the drawer module 13 is withdrawn from the chassis 12 and while the chassis 12 is withdrawn from the cabinet body 11, the first section 1432 of the movable member 143 is disengaged from the cabinet body 11, and the guiding surface P1 guides the locking member 142 from the first section 1432 to the second section 1433, so that the locking member 142 is located at the rotation path of the rotating member 141, the locking member 142 cooperates with the chassis 12 to limit the rotating member 141 to rotate, so that the drawer module 13 is restricted from being withdrawn from the chassis 12 after the chassis 12 is withdrawn from the cabinet body 11.

After the chassis 12 is completely withdrawn from the cabinet body 11, the movable member 143 moves in the opposite direction of the first direction D1 relative to the locking member 142, and the locking member 142 is moved from the second section 1433 to the third section 1434 to move the locking member 142 away from the rotation path of the rotating member 141, and the rotating member 141 is allowed to rotate. By operating the grasping portion 1411 to rotate the rotating member 141, and the rotating member 141 is separated from the chassis 12. In the unlocked state, the drawer module 13 is withdrawn from the chassis 12.

Even though numerous characteristics and advantages of the present technology have been set forth in the foregoing description, together with details of the structure and function of the present application, the application is illustrative only, and changes can be made in the detail, especially in matters of shape, size, and arrangement of the parts within the principles of the present application, up to and including the full extent established by the broad general meaning of the terms used in the claims. It will, therefore, be appreciated that the exemplary embodiments described above can be modified within the scope of the claims.

What is claimed is:

1. A cabinet comprising a cabinet body, a chassis, a drawer module, and a locking mechanism, wherein:
the chassis is disposed in the cabinet body, and the chassis is withdrawable from the cabinet body along a first direction;
the drawer module is disposed in the chassis, and the drawer module is withdrawable from the chassis along the first direction; and
the locking mechanism comprises a rotating member and a locking member, the rotating member is rotationally disposed in the drawer module and abuts against the chassis, a rotation plane of the rotating member is parallel to the first direction; the locking member is movably disposed in the chassis along a second direction to be located at or away from a rotation path of the rotating member, and the second direction is orthogonal to the rotation plane of the rotating member;
in a locked state, the rotating member abuts against the chassis, and the drawer module is restricted from being withdrawn from the chassis; the rotating member is separated from the chassis during rotation; in an unlocked state, the rotating member is separated from the chassis, and the drawer module can be withdrawn from the chassis; and when the chassis is withdrawn from the cabinet body, the rotating member abuts against the chassis, the locking member is located at the rotation path of the rotating member, and the chassis cooperates with the locking member to limit a rotation of the rotating member.

2. The cabinet according to claim 1, wherein the cabinet further comprises an elastic member connected between the drawer module and the rotating member, the elastic member is configured to hold the rotating member against the chassis before the rotating member rotates.

3. The cabinet according to claim 1, wherein the locking mechanism further comprises a movable member, the movable member is disposed on the drawer module, the movable member defines a channel that extends along a second direction, and the locking member is movably disposed in the channel; the movable member comprises a first section and a second section connected to the first section along the first direction, the channel is connected to the first section and the second section, the first section is configured to contact the locking member and to move the locking member away from the rotation path of the rotating member, and the second section is configured to contact the locking member and to move the locking member in the rotation path of the rotating member; along the second direction, the second section is closer to the rotation plane of the rotating member compared to the first section.

4. The cabinet according to claim 3, wherein the first section comprises a guiding surface, the guiding surface is connected the channel, and the guiding surface is configured to guide the locking member to move from the first section to the second section.

5. The cabinet according to claim 3, wherein the second section comprises a positioning surface, the positioning surface connects the channel, and the positioning surface is configured to keep the locking member in the second section.

6. The cabinet according to claim 4, wherein the first section is further configured to abut against the cabinet before the chassis is withdrawn from the cabinet to keep the locking member in the guiding surface; and the first section is further configured to disengage from the cabinet after the chassis is withdrawn from the cabinet to allow the guiding surface to guide the locking member to move from the first section to the second section.

7. The cabinet according to claim 4, wherein the movable member further comprises a third section connected to the second section along the first direction, and the channel is connected to third section; along the second direction, the third section is further away from the rotation plane of the rotating member compared to the second section, and the third section is configured to contact the locking member and maintain the locking member away from the rotation path of the rotating member.

8. The cabinet according to claim 7, wherein the third section comprises a limiting surface, the limiting surface is connected to channel, and the limiting surface is configured to keep the locking member in the third section.

9. The cabinet according to claim 3, wherein the locking member comprises a cap portion and a rod portion connected to the cap portion, the rod portion is movable in the channel, and the cap portion contacts the movable member; along the second direction, a projection of part of the cap portion exceeds a projection of the channel.

10. The cabinet according to claim 9, wherein the locking mechanism further comprises an auxiliary member, the auxiliary member is slidably disposed on the movable member, the auxiliary member defines a through hole that penetrates along the second direction; along the second direction, the through hole is disposed in the projection of the channel; and the rod portion is movable in the through hole to be located at or away from the rotation path of the rotating member.

11. A cabinet comprising a cabinet body, a chassis, a drawer module, and a locking mechanism, wherein:
the chassis is disposed in the cabinet body, and the chassis is withdrawable from the cabinet body along a first direction;
the drawer module is disposed in the chassis, and the drawer module is withdrawable from the chassis along the first direction; and
the locking mechanism comprises a rotating member and a locking member, the rotating member is rotationally disposed in the drawer module and abuts against the chassis, a rotation plane of the rotating member is parallel to the first direction; the locking member is movably disposed in the chassis along a second direction to be located at or away from a rotation path of the rotating member, and the second direction is orthogonal to the rotation plane of the rotating member;
in a locked state, the rotating member abuts against the chassis, and the drawer module is restricted from being withdrawn from the chassis; the rotating member is separated from the chassis during rotation; in an unlocked state, the rotating member is separated from the chassis, and the drawer module can be withdrawn from the chassis; and when the chassis is withdrawn from the cabinet body, the rotating member abuts against the chassis, the locking member is located at the rotation path of the rotating member, and the chassis cooperates with the locking member to limit a rotation of the rotating member;
wherein the cabinet further comprises an elastic member, and the elastic member is connected between the drawer module and the rotating member, and the elastic member is configured to hold the rotating member against the chassis before the rotating member rotates; and
wherein the locking mechanism further comprises a movable member, the movable member is disposed on the drawer module, the movable member defines a channel that extends along a second direction, and the locking member is movably disposed in the channel.

12. The cabinet according to claim 11, wherein the movable member comprises a first section and a second section connected to the first section along the first direction, the channel is connected to the first section and the second section, the first section is configured to contact the locking member and to move the locking member away from the rotation path of the rotating member, and the second section is configured to contact the locking member and to move the locking member in the rotation path of the rotating member; along the second direction, the second section is closer to the rotation plane of the rotating member compared to the first section.

13. The cabinet according to claim 12, wherein the first section comprises a guiding surface, the guiding surface is connected the channel, and the guiding surface is configured to guide the locking member to move from the first section to the second section.

14. The cabinet according to claim 12, wherein the second section comprises a positioning surface, the positioning surface connects the channel, and the positioning surface is configured to keep the locking member in the second section.

15. The cabinet according to claim 13, wherein the first section is further configured to abut against the cabinet before the chassis is withdrawn from the cabinet to keep the locking member in the guiding surface; and the first section is further configured to disengage from the cabinet after the chassis is withdrawn from the cabinet to allow the guiding surface to guide the locking member to move from the first section to the second section.

16. The cabinet according to claim 13, wherein the movable member further comprises a third section connected to the second section along the first direction, and the channel is connected to third section; along the second direction, the third section is further away from the rotation plane of the rotating member compared to the second section, and the third section is configured to contact the locking member and maintain the locking member away from the rotation path of the rotating member.

17. The cabinet according to claim 16, wherein the third section comprises a limiting surface, the limiting surface is connected to channel, and the limiting surface is configured to keep the locking member in the third section.

18. The cabinet according to claim 12, wherein the locking member comprises a cap portion and a rod portion connected to the cap portion, the rod portion is movable in the channel, and the cap portion contacts the movable member; along the second direction, a projection of part of the cap portion exceeds a projection of the channel.

19. The cabinet according to claim 18, wherein the locking mechanism further comprises an auxiliary member, the auxiliary member is slidably disposed on the movable member, the auxiliary member defines a through hole that penetrates along the second direction; along the second direction, the through hole is disposed in the projection of the channel.

20. The cabinet according to claim 19, wherein the rod portion is movable in the through hole to be located at or away from the rotation path of the rotating member.
